(19) United States
(12) Patent Application Publication
(10) Pub. No.: US 2026/0160933 A1
(43) Pub. Date: Jun. 11, 2026

(54) WIRE GRID POLARIZER, DISPLAY DEVICE INCLUDING THE SAME, ELECTRONIC DEVICE INCLUDING THE SAME, AND MANUFACTURING METHOD OF WIRE GRID POLARIZER

(71) Applicant: Samsung Display Co., Ltd., Yongin-Si (KR)

(72) Inventors: SAMTAE JEONG, Yongin-si (KR); Hong Yeon LEE, Yongin-si (KR)

(21) Appl. No.: 19/385,406

(22) Filed: Nov. 11, 2025

(30) Foreign Application Priority Data
Dec. 11, 2024 (KR) 10-2024-0184002

(51) Int. Cl. G02B 5/30; H10K 59/12; H10K 59/80

(52) U.S. Cl. CPC G02B 5/3058; H10K 59/1201; H10K 59/8793

(57) ABSTRACT

A wire grid polarizer according to an embodiment includes a first layer; and a plurality of metal patterns that are disposed on the first layer and have good etching selectivity to the first layer, and the first layer includes at least one groove.

### CROSS-REFERENCE TO RELATED APPLICATION

This application claims priority to and the benefit of Korean Patent Application No. 10-2024-0184002 filed at the Korean Intellectual Property Office on Dec. 11, 2024, the entire contents of which are incorporated herein by reference.

### BACKGROUND

### (a) Field

The present disclosure relates to a wire grid polarizer, a display device including the wire grid polarizer, an electronic device including the same, and a method of manufacturing the wire grid polarizer.

### (b) Description of the Related Art

A polarizer (or a polarizing layer) is used to pass light only in a specific direction. In a wire grid polarizer, metal wires are disposed side by side at intervals narrower than a wavelength of an incident electromagnetic wave so that the wire grid polarizer selectively transmits or reflects the electromagnetic wave according to its polarization.

Wire grid polarizers have an advantage of having a polarization effect, high reflectivity, and high conductivity, and they are widely applied to display screens of mobile phones, ARs, VRs, or the like because wire grid polarizers improve light efficiency, viewing angle, and the like.

### SUMMARY

Embodiments are intended to provide a wire grid polarizer with a simple manufacturing process, a display device including the wire grid polarizer, an electronic device including the display device, and a method of manufacturing the wire grid polarizer.

The wire grid polarizer according to an embodiment of the present disclosure includes: a first layer; and a plurality of metal patterns that are disposed on the first layer and have good etching selectivity to the first layer, and the first layer includes at least one groove.

The at least one groove may be disposed between metal patterns adjacent to each other.

The first layer includes a transparent conductive oxide.

The first layer includes a plurality of grooves and the plurality of grooves may be repeatedly disposed.

The first layer includes a plurality of grooves, the plurality of grooves may include a first groove and a second groove, and the first groove and the second groove may have different depths.

The display device according to an embodiment includes: a display layer that includes a light emitting device; and a wire grid polarizer that is disposed on the display layer, and the wire grid polarizer includes a first layer including a transparent conductive oxide and a plurality of metal patterns disposed on the first layer and having good etching selectivity to the first layer, and the first layer includes at least one groove.

The electronic device according to an embodiment includes a display device, and the display device includes a display layer including a light emitting device and a wire grid polarizer disposed on the display layer, the wire grid polarizer includes a first layer including a transparent conductive oxide and a plurality of metal patterns disposed on the first layer and having good etching selectivity to the first layer, and the first layer includes at least one groove.

The first layer may include a plurality of grooves, and the plurality of grooves may be repeatedly disposed.

The plurality of grooves may include a first groove and a second groove, and the first groove and the second groove may have different depths.

The manufacturing method of a wire grid polarizer according to an embodiment includes: forming a first metal material layer on an etching prevention material layer; forming a first photosensitive pattern on the first metal material layer; forming a first semiconductor layer on the first photosensitive pattern by an oblique angle deposition method; and etching the first metal material layer using the first semiconductor layer as a mask to form a second metal material layer.

The manufacturing method may further include: removing the first photosensitive pattern and the first semiconductive layer after etching the first metal material layer.

The manufacturing method may further include: forming a second photosensitive pattern on the second metal material layer and the etching prevention material layer; forming a second semiconductor layer on the second photosensitive pattern by the oblique angle deposition method; and etching the second metal material layer using the second semiconductor layer as a mask.

The manufacturing method may further include removing the second photosensitive pattern and the second semiconductor layer.

The first layer may include at least one groove.

The first layer may include a plurality of grooves, and the plurality of grooves may be repeatedly disposed.

The plurality of grooves may include a first groove and a second groove, and the first groove and the second groove may have different depths.

An interval between adjacent metal patterns may be less than a width of the first photosensitive pattern.

The first semiconductor layer may be deposited on the first metal material layer in an oblique deposition direction through the oblique angle deposition method.

A non-deposition area where the first semiconductor layer is not disposed may be formed through the oblique angle deposition method.

The first metal material layer overlapping the non-deposition area may be removed.

According to the embodiments, the manufacturing process of the wire grid polarizer may be simplified. In addition, the embodiments may provide a wire grid polarizer applied to a large-area display device.

### BRIEF DESCRIPTION OF THE DRAWINGS

FIG. 1 is a block diagram of an electronic device according to an embodiment.

FIG. 2 is a schematic diagram of electronic devices according to various embodiments.

FIG. 3 is a schematic plan view of a display device according to an embodiment.

FIG. 4 is a cross-sectional view of one pixel of a display device according to an embodiment.

FIG. 5 is a cross-sectional view of a wire grid polarizer according to an embodiment.

FIG. 6 is a cross-sectional view of one pixel of a display device according to an embodiment.

FIG. 7 is a cross-sectional view of a wire grid polarizer according to an embodiment.

FIGS. 8, 9, 10, 11, 12, 13, 14, 15, 16, 17, 18, 19, 20, 21, 22, 23, 24, 25 and 26 are cross-sectional views of a manufacturing process of a wire grid polarizer according to an embodiment.

### DETAILED DESCRIPTION OF THE EMBODIMENTS

Embodiments of the present disclosure will be described more fully hereinafter with reference to the accompanying drawings so that those skilled in the art could easily implement the embodiments. The present disclosure may be modified in various ways, all without departing from the spirit or scope of the present disclosure.

In order to clearly describe the present disclosure, parts or portions that are irrelevant to the description are omitted, and identical or similar constituent elements throughout the specification are denoted by the same reference numerals.

In the drawings, a size and a thickness of each element are arbitrarily illustrated for ease of description, and the present disclosure is not necessarily limited to what is illustrated in the drawings. In the drawings, the thicknesses of some layers and areas are exaggerated for clarity. In the drawings, for ease of description, the thicknesses of some layers and areas are exaggerated.

It should be understood that when an element such as a layer, a film, a region, or a plate is referred to as being “on” or “above” another element, it may be directly on the other element, or an intervening element may also be present. In contrast, when an element is referred to as being “directly on” another element, there are no intervening elements present. Further, in the specification, the word “on” or “above” means disposed on or below a referenced part, and does not necessarily mean disposed on the upper side of the referenced part based on a gravitational direction.

Unless explicitly stated to the contrary, the word “comprise” and variations such as “comprises” and “comprising” should be understood to imply the inclusion of stated elements but not the exclusion of any other elements.

Throughout the specification, the phrase “in a plan view” or “on a plane” may mean when an object portion is viewed from above, and the phrase “in a cross-sectional view” or “in a cross-section” may mean when a cross-section taken by vertically cutting an object portion is viewed from the side.

A display device according to an embodiment may be applied to various electronic devices. An electronic device according to an embodiment may include the display device described below, and may further include a module or a device having other functions in addition to the display device.

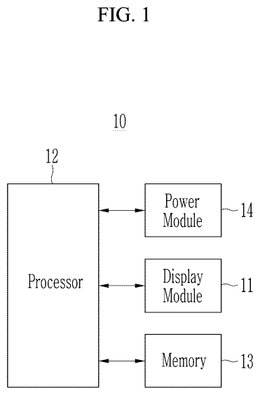

FIG. 1 is a block diagram of the electronic device according to the embodiment.

Referring to FIG. 1, an electronic device 10 according to the embodiment may include a display module 11, a processor 12, a memory 13, and a power module 14.

The processor 12 may include at least one of a central processing unit (CPU), an application processor (AP), a graphic processing unit (GPU), a communication processor (CP), an image signal processor (ISP), and a controller.

Data information necessary for operation of the processor 12 or the display module 11 may be stored in the memory 13. If the processor 12 executes an application stored in the memory 13, an image data signal and/or an input control signal may be transferred to the display module 11, and the display module 11 may process a received signal and may output image information through a display screen.

The power module 14 may include a power supply module such as a power adapter or a battery device, and a power conversion module that converts power supplied by the power supply module to generate power required for operation of the electronic device 10.

At least one of the components of the electronic device 10 described above may be included in the display device according to the embodiments. Additionally, some of individual modules functionally included within one module may be included within the display device, and others of the individual modules functionally included within a single module may be provided separately from the display device. For example, the display device may include the display module 11, and the processor 12, the memory 13, and the power module 14 may be provided in a form of another device within the electronic device 10 other than the display device.

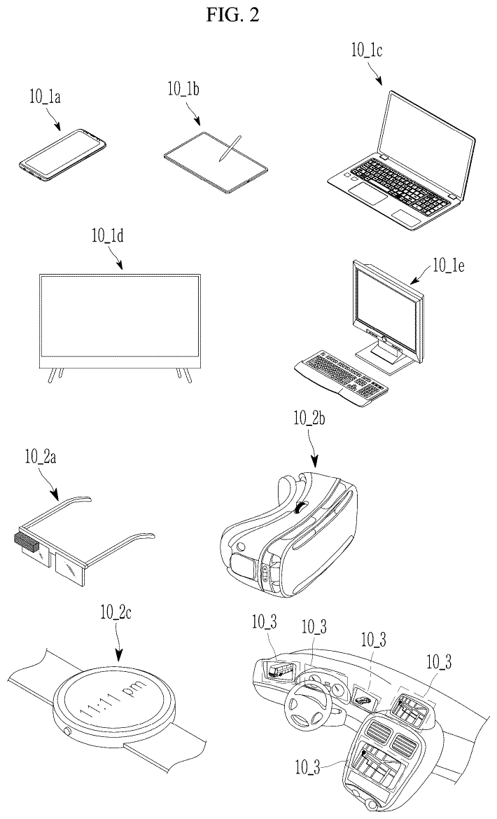

Hereinafter, various embodiments of electronic devices will be described with reference to FIG. 2. FIG. 2 is a schematic diagram of electronic devices according to various embodiments.

Referring to FIG. 2, various electronic devices to which the display devices according to embodiments are applied may include an image display electronic device such as a smartphone 10_1a, a tablet PC 10_1b, a laptop 10_1c, a TV 10_1d, or a desk monitor 10_1e, a wearable electronic device including a display module such as smartglasses 10_2a, a head mounted display 10_2b, or a smartwatch 10_2c, and a vehicle electronic device 10_3 including a display module such as a center information display (CID) or a room mirror display disposed on an instrument panel, a center fascia, or a dashboard of a vehicle, and the like.

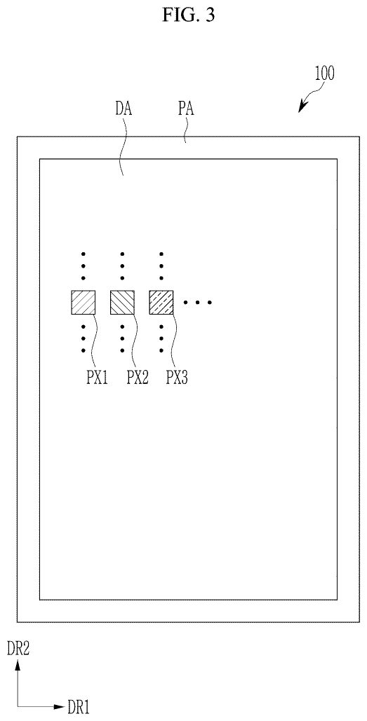

Hereinafter, a display device included in an electronic device according to an embodiment will be described with reference to FIG. 3. FIG. 3 is a schematic plan view of the display device according to the embodiment. The display module described in FIG. 1 may be a display device that displays an image.

The display device 100 according to the embodiment may be a display device such as an organic light emitting display device, a liquid crystal display device, an organic light emitting diode on silicon substrate (OLEDos), a liquid crystal on silicon substrate (LCos), or a light emitting diode on silicon substrate (LEDos).

Referring to FIG. 3, the display device 100 according to the embodiment may include a display area DA and a non-display area PA. The display area DA may be an area that generates light or displays an image by adjusting an intensity of light provided from an external light source. The non-display area PA may be an area that does not display an image. The non-display area PA may be disposed around the display area DA. For example, the non-display area PA may entirely surround the display area DA.

The display area DA may include a plurality of pixel areas PX1, PX2, and PX3. The pixel areas PX1, PX2, and PX3 may be disposed in a matrix form along a first direction DR1 and a second direction DR2 intersecting the first direction DR1. The pixel areas PX1, PX2, and PX3 may include the first pixel area PX1, the second pixel area PX2, and the third pixel area PX3.

Each of the first pixel area PX1, the second pixel area PX2, and the third pixel area PX3 may mean an area in which light emitted from a light emitting device is emitted to the outside of the display device 100. For example, the first pixel area PX1 may emit a first light, the second pixel area PX2 may emit a second light, and the third pixel area PX3 may emit a third light. In an embodiment, the first light may be red light, the second light may be green light, and the third light may be blue light. However, the present disclosure is not limited thereto. For example, the first to third pixel areas PX1, PX2, and PX3 may be combined to emit yellow, cyan, and magenta light. The first to third pixel areas PX1, PX2, and PX3 may emit light of four or more colors. For example, in addition to the first to third pixel areas PX1, PX2, and PX3, the pixel areas may further include at least one pixel area which emits at least one of yellow, cyan, and magenta lights. Additionally, the pixel areas may further include a pixel area which emits white light.

Each of the first pixel area PX1, the second pixel area PX2, and the third pixel area PX3 may have a triangular planar shape, a quadrangular planar shape, a circular planar shape, a track-shaped planar shape, an elliptical planar shape, or the like. In an embodiment, each of the first pixel area PX1, the second pixel area PX2, and the third pixel area PX3 may have a quadrangular planar shape. However, the present disclosure is not limited thereto, and the first pixel area PX1, the second pixel area PX2, and the third pixel area PX3 may have different planar shapes.

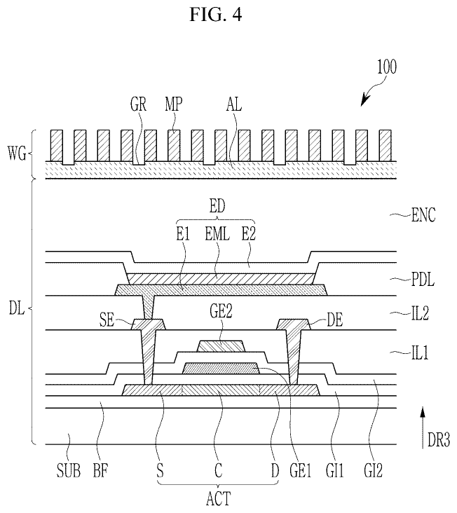

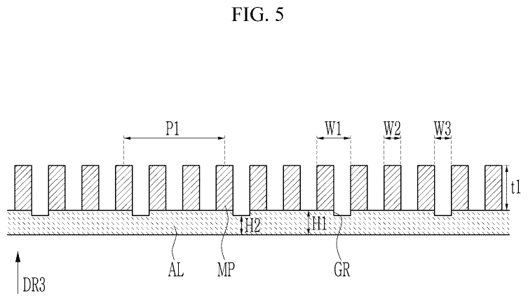

Hereinafter, a stacking structure of a display device according to an embodiment will be described with reference to FIG. 4 and FIG. 5. FIG. 4 is a cross-sectional view of one pixel area of a display device according to an embodiment. and FIG. 5 is a cross-sectional view of a wire grid polarizer according to an embodiment.

Referring to FIG. 4, the display device 100 according to the embodiment may include a display layer DL and a wire grid polarizer WG. The display layer DL may include a transistor and a light emitting device electrically connected to the transistor. The wire grid polarizer WG may be disposed on the display layer DL.

Hereinafter, the display layer DL will be first described.

Referring to FIG. 4, a buffer layer BF may be disposed on a substrate SUB. In some embodiments, the buffer layer BF may be omitted. The buffer layer BF may include silicon nitride, silicon oxide, silicon oxynitride, or the like. The buffer layer BF may improve characteristics of a semiconductor layer by blocking impurities from the substrate SUB during a crystallization process for forming the polycrystalline silicon. Additionally, the buffer layer BF may planarize the substrate SUB to alleviate stress on a semiconductor layer ACT formed on the buffer layer BF.

The semiconductor layer ACT may be disposed on the buffer layer BF. The semiconductor layer ACT may include polycrystalline silicon or an oxide semiconductor. The semiconductor layer ACT may include a channel area C, a source area S, and a drain area D. Each of the source area S and drain area D may be disposed on both sides of the channel area C. The channel area C may include an intrinsic semiconductor that is not doped with or is hardly doped with impurities, and each of the source area S and the drain area D may include a doped semiconductor that is doped with conductive impurities. The semiconductor layer ACT may include an oxide semiconductor, and in this case, a separate protective layer (not shown) may be added to protect an oxide semiconductor material vulnerable to an external environment such as high temperature.

A first gate insulating layer GI1 may be disposed on the semiconductor layer ACT. The first gate insulating layer GI1 may be a single layer or multiple layers including at least one of silicon nitride, silicon oxide, and silicon oxynitride.

A gate electrode GE1 may be disposed on the first gate insulating layer GI1. The gate electrode GE1 may overlap the channel area C of the semiconductor layer ACT. The gate electrode GE1 may be a multilayer in which a metal layer including any one of copper (Cu), a copper alloy, aluminum (Al), an aluminum alloy, molybdenum (Mo), and a molybdenum alloy is stacked.

A second gate insulating layer GI2 may be disposed on the gate electrode GE1. The second gate insulating layer GI2 may be a single layer or multiple layers including at least one of silicon nitride, silicon oxide, and silicon oxynitride.

A storage electrode GE2 may be disposed on the second gate insulating layer GI2. The storage electrode GE2 may form a capacitor with the gate electrode GE1 and the second gate insulating layer GI2 disposed between the gate electrode GE1 and the storage electrode GE2. A first interlayer insulating layer IL1 may be disposed on the storage electrode GE2.

A source electrode SE and a drain electrode DE may be disposed on the first interlayer insulating layer IL1. The source electrode SE and the drain electrode DE may be electrically connected to the source area S and the drain area D of the semiconductor layer ACT, respectively, through contact holes defined in a plurality of insulating layers disposed under the source electrode SE and the drain electrode DE.

A second interlayer insulating layer IL2 may be disposed on the source electrode SE and the drain electrode DE. The second interlayer insulating layer IL2 may include an inorganic insulating material or an organic insulating material.

A transistor including the gate electrode GE1, the semiconductor layer ACT, the source electrode SE, and the drain electrode DE may be electrically connected to a first electrode E1 of a light emitting device ED to supply a driving current to a light emitting device ED. In addition to a driving transistor shown in FIG. 4, the display device according to an embodiment may further include a switching transistor (not shown) that is connected to a data line and transfers a data voltage in response to a scan signal, and a compensation transistor (not shown) that is connected to the driving transistor and compensates for a threshold voltage of the driving transistor in response to the scan signal.

The first electrode E1 may be disposed on the second interlayer insulating layer IL2. The first electrode E1 may include a metal, an alloy, metal nitride, conductive metal oxide, a transparent conductive material, or the like. These may be used alone or in combination with each other.

The first electrode E1 may be an anode electrode of the light emitting device ED. The first electrode E1 may be a reflective electrode.

A pixel defining layer PDL may be disposed on the second interlayer insulating layer IL2 and the first electrode E1. The pixel defining layer PDL may have a pixel opening portion that is disposed in an area corresponding to the first electrode E1 and defines a light emitting area. The pixel opening portion may have a planar shape almost similar to that of the first electrode E1, and may have a quadrangular shape, a rhombus shape, or an octagonal shape similar to the rhombus shape in a plan view, but the present disclosure is not limited thereto, and the pixel opening portion may have any shape such as a circle, an ellipse, or a polygon.

The pixel defining layer PDL may include an organic material such as a polyacrylates resin or a polyimides resin, or a silica-based inorganic material.

A light emitting layer EML may be disposed on the first electrode E1 in the area corresponding to the pixel opening portion. The light emitting layer EML may be formed of a low-molecular weight organic material or a polymer organic material such as PEDOT (poly 3,4-ethylenedioxythiophene). In addition to the light emitting layer EML, a hole injection layer (HIL) and a hole transporting layer (HTL) may be disposed on one side of the light emitting layer EML, and an electron transporting layer (ETL) and an electron injection layer (EIL) may be disposed on another side of the light emitting layer EML opposing the one side of the light emitting layer EML.

Most of the light emitting layer EML may be disposed within the pixel opening portion, and, according to an embodiment, the light emitting layer EML may be disposed on a side surface of the pixel defining layer PDL or on the pixel defining layer.

A second electrode E2 may be disposed on the light emitting layer EML. The second electrode E2 may be disposed over a plurality of pixels, and may receive a common voltage through a common voltage transferring portion (not shown) disposed in the non-display area.

The first electrode E1, the light emitting layer EML, and the second electrode E2 may form the light emitting device ED.

The first electrode E1 may be an anode that is a hole injection electrode and the second electrode E2 may be a cathode that is an electron injection electrode. However, the embodiment is not necessarily limited thereto and the first electrode E1 may be a cathode and the second electrode E2 may be an anode according to a driving method of the organic light emitting display device.

A hole and an electron may be each injected into the light emitting layer EML from the first electrode E1 and the second electrode E2, respectively, and light emission may occur when an exciton formed by combining the injected hole and electron drops from an exited state to a ground state.

An encapsulation layer ENC may be disposed on the second electrode E2. The encapsulation layer ENC may seal not only an upper surface but also a side surface of the display layer including the light emitting device ED to seal the display layer. Because the light emitting device is very vulnerable to moisture and oxygen, the encapsulation layer ENC may seal the display layer to block inflow of external moisture and oxygen to the light emitting device. The encapsulation layer ENC may include a plurality of layers, may be formed of a composite layer including both an inorganic layer and an organic layer, and may be formed of a triple layer in which a first inorganic layer, an organic layer, and a second inorganic layer are sequentially formed.

The wire grid polarizer WG may be disposed on the encapsulation layer ENC. Although the present specification illustrates the wire grid polarizer WG disposed on the encapsulation layer ENC, the present disclosure is not limited thereto, and the wire grid polarizer WG may be stacked at various positions within the display device.

According to an embodiment, the wire grid polarizer WG may include a first layer AL and a plurality of metal patterns MP. The plurality of metal patterns MP may be disposed on the first layer AL. The wire grid polarizer WG may selectively control polarization of light through a fine metal pattern MP, and may provide high transmittance and efficiency of light without a separate polarizing plate.

A material constituting the fine metal pattern MP may have a good etching selectivity to the first layer. The first layer AL may include transparent conductive oxide (TCO). For example, the first layer AL may include indium-tin oxide (ITO), aluminum-doped zinc oxide (AZO), fluorine-doped tin oxide (FTO), or the like.

The first layer AL may be an etching prevention layer that prevents excessive etching of layers disposed below the first layer AL in a process of manufacturing the plurality of metal patterns MP. The first layer AL may be a layer having good etching selectivity to a metal layer forming the fine metal pattern MP. A thickness of the first layer AL may range from about 100 angstroms (Å) to about 1500 angstroms (Å).

According to an embodiment, the first layer AL may include a grooves GR disposed between adjacent metal patterns. Grooves GR may be repeatedly disposed in the first layer AL.

The plurality of metal patterns MP may include a metal such as aluminum (Al), gold (Au), silver (Ag), copper (Cu), chromium (Cr), iron (Fe), nickel (Ni), titanium nitride, ITO, or MTO, metal oxide, or metal nitride. These may be used alone or in combination with each other.

The plurality of metal patterns MP may be disposed along one direction. In addition, the metal pattern MP may have a stripe shape extending in a direction perpendicular to the one direction.

Hereinafter, a detailed structure of the wire grid polarizer WG will be described with reference to FIG. 5.

Referring to FIG. 5, the first layer AL may include a plurality of grooves GR. According to a manufacturing process described below, the first layer AL may include an area that is etched at least two times during the manufacturing process. The area that is etched at least two times may be exposed to the etchant more times than other areas that are etched once. Therefore, because the area that is etched at least two times is additionally etched, the area that is etched at least two times may have a recessed portion recessed from an upper surface of the first layer AL. The grooves GR described in the present specification may refer to grooves or recessed portions formed in the first layer AL.

The plurality of grooves GR may be periodically repeated. For example, one groove GR may be included in one period P1 in which at least two metal patterns and at least two spaces are disposed. However, the present disclosure is not limited thereto and may be modified to include one or more grooves GR within the one period P1. For example, adjacent grooves GR may be disposed to have three metal patterns MP interposed therebetween, but the present disclosure is not limited thereto. At least one to five metal patterns MP may be disposed between the adjacent grooves GR.

The first layer AL may include a first portion having a first height H1 and a second portion having a second height H2. The second portion may refer to an area where the groove GR is formed. The first height H1 may be greater than the second height H2. For example, the second height H2 may be greater than or equal to 50% and less than 100% of the first height H1.

A thickness of the first layer AL may range from about 100 angstroms (Å) to about 1500 angstroms (Å). That is, the first height H1 may range from about 100 angstroms (Å) to about 1500 angstroms (Å).

The plurality of metal patterns MP may be disposed along one direction. The plurality of metal patterns MP may be repeatedly disposed at regular intervals.

A cross-sectional width W2 of one metal pattern MP may be about 100 nanometers to about 500 nanometers. Additionally, an interval W3 between adjacent metal patterns MP may be about 100 nanometers to about 500 nanometers. That is, a period W1 which includes one space between adjacent metal patterns MP and one metal pattern MP may be about 200 nanometers to about 1000 nanometers. A height t1 of each metal pattern MP may be about 1000 angstroms (Å) to about 3000 angstroms (Å).

There may be a gap between the adjacent metal patterns MP. The grooves GR may be disposed between the metal patterns MP. The metal pattern MP may not be disposed on the grooves GR.

Although the metal pattern MP according to the present specification illustrates the embodiment including a single layer, the present disclosure is not limited thereto, and the metal pattern MP may be formed of a double layer or a triple layer. For example, the metal pattern MP may be formed of a multilayer including at least one of aluminum, titanium, titanium nitride, ITO, and MTO. For example, the metal pattern MP may be formed of a double layer of aluminum and titanium, a double layer of aluminum and MTO, a double layer of aluminum and titanium nitride, or a double layer of aluminum and ITO.

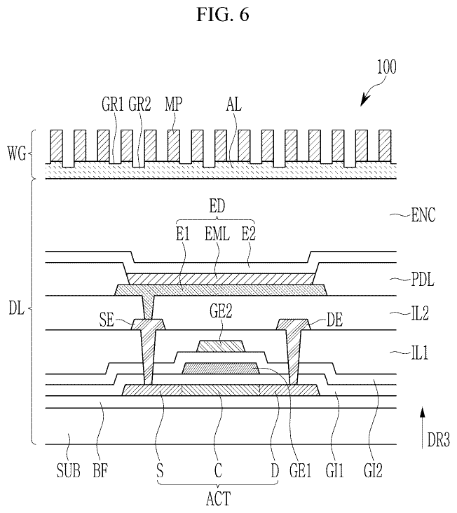

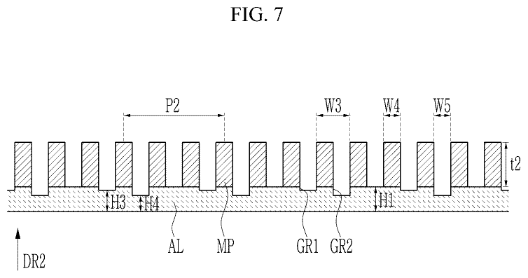

Hereinafter, a stacking structure of the display device according to an embodiment will be described with reference to FIG. 6 and FIG. 7. FIG. 6 is a cross-sectional view of one pixel area of the display device according to an embodiment, and FIG. 7 is a cross-sectional view of the wire grid polarizer according to an embodiment. A description of the same components as those described above will be omitted.

Referring to FIG. 6 and FIG. 7, the wire grid polarizer WG may be disposed on the display layer DL. The wire grid polarizer WG may include the first layer AL and the plurality of metal patterns MP. The plurality of metal patterns MP may be disposed on the first layer AL along one direction. The plurality of metal patterns MP may be repeatedly disposed at regular intervals.

The first layer AL may be disposed on the display layer DL. However, the present disclosure is not limited thereto and a position at which the wire grid polarizer WG is disposed may be changed according to a structure of a display panel.

The first layer AL may include a plurality of grooves GR1 and GR2. The first layer AL may include a first grooves GR1 and a second grooves GR2. Heights of the first grooves GR1 and the second grooves GR2 may be different. The first grooves GR1 and the second grooves GR2 may have different depths.

A thickness H3 of the first layer AL that overlaps the first grooves GR1 may be greater than a thickness H4 of the first layer AL that overlaps the second grooves GR2. The first grooves GR1 may be exposed to the etching process a relatively small number of times than the second grooves GR2, and, as a result, a depth of the first grooves GR1 may be relatively small. On the other hand, the second grooves GR2 may be exposed to the etching process a relatively large number of times than the first grooves GR1, and, as a result, a depth of the second groove GR2 may be relatively large. The first layer AL may have a flat upper surface except in areas other than areas in which the first grooves GR1 and the second grooves GR2 are disposed. The first layer AL may have the first height H1 at areas where the grooves GR1 and GR2 are not disposed.

A thickness of the first layer AL may be about 100 angstroms (Å) to about 1500 angstroms (Å). That is, the first height H1 may be about 100 angstroms (Å) to about 1500 angstroms (Å). For example, each of a third height H3 and a fourth height H4 may be greater than or equal to 50% and less than 100% of the first height H1.

The first groove GR1 and the second groove GR2 may be periodically repeated. For example, one first groove GR1 and one second groove GR2 may be included in one period P2. The one period P2 may include four metal patterns MP. The number of metal patterns MP included in the one period P2 may be variously changed. When the one period P2 includes one first groove GR1 and one second groove GR2, the number of metal patterns MP included in the one period P2 may be at least 1 to 10.

The plurality of metal patterns MP may be disposed on the first layer AL. Adjacent metal patterns MP may be spaced apart from each other with the first groove GR1 interposed therebetween. Additionally, other adjacent metal patterns MP may be spaced apart from each other with the second groove GR2 interposed therebetween.

A cross-sectional width W4 of one metal pattern MP may be about 100 nanometers to about 500 nanometers. Additionally, an interval W5 between adjacent metal patterns MP may be about 100 nanometers to about 500 nanometers. That is, a period W3 which includes one space between adjacent metal patterns MP and one metal pattern MP may be about 200 nanometers to about 1000 nanometers. A height t2 of each metal pattern MP may be about 1000 angstroms (Å) to about 3000 angstroms (Å).

There may be a gap between the adjacent metal patterns MP. The first groove GR1 and the second groove GR2 may be disposed between adjacent metal patterns MP. The metal pattern MP may not be disposed on the first groove GR1 or the second groove GR2.

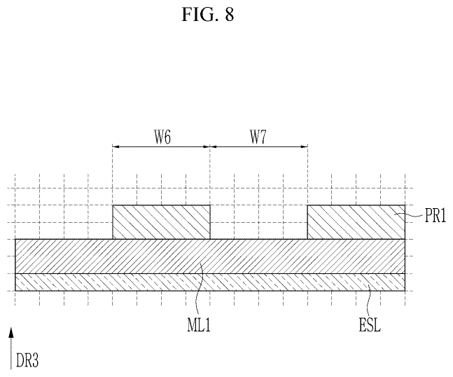

Hereinafter, a manufacturing process of the wire grid polarizer according to an embodiment will be described with reference to FIGS. 8 to 26. FIGS. 8 to 26 are cross-sectional views of the manufacturing process of the wire grid polarizer according to an embodiment. A description of the same components as those described above will be omitted. In addition, the manufacturing process of the wire grid polarizer formed on the display layer will be described, but the manufacturing process and a stacking structure of the display layer will be omitted.

First, referring to FIG. 8, an etching prevention material layer ESL may be formed. The etching prevention material layer ESL may include transparent conductive oxide (TCO). For example, the etching prevention material layer ESL may include indium-tin oxide (ITO), aluminum-doped zinc oxide (AZO), fluorine-doped tin oxide (FTO), or the like.

Next, a first metal material layer ML1 may be formed on the etching prevention material layer ESL. The first metal material layer ML1 may include a material such as aluminum (Al), gold (Au), silver (Ag), copper (Cu), chromium (Cr), iron (Fe), nickel (Ni), titanium nitride, ITO, MTO, or the like. These may be used alone or in combination with each other.

A thickness of the first metal material layer ML1 may be about 1000 angstroms (Å) to about 3000 angstroms (Å). The first metal material layer ML1 may have a generally flat thickness.

A first photosensitive pattern PR1 may be disposed on the first metal material layer ML1. A plurality of first photosensitive patterns PR1 may be disposed on the first metal material layer ML1. The plurality of first photosensitive patterns PR1 may be repeatedly disposed. The plurality of first photosensitive patterns PR1 may be disposed at regular intervals from each other. A width W6 of the first photosensitive pattern PR1 and an interval W7 between adjacent first photosensitive patterns PR1 may be the same. For example, the width W6 of the first photosensitive pattern PR1 may be about 1 micrometer, and the interval W7 between the adjacent first photosensitive patterns PR1 may be about 1 micrometer. The width W6 of the first photosensitive pattern PR1 and the interval W7 between the adjacent first photosensitive patterns PR1 may vary according to an exposure capability of an exposure machine.

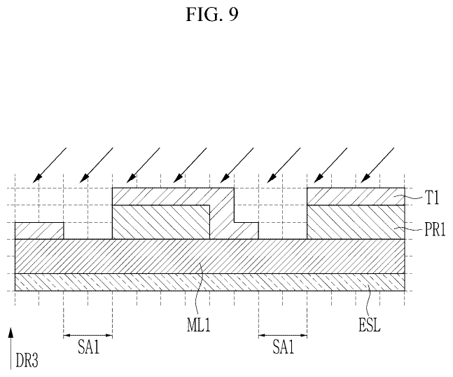

Next, referring to FIG. 9, a first semiconductor layer T1 may be formed on the first photosensitive pattern PR1. For example, the first semiconductor layer T1 may include an oxide semiconductor such as IGZO, IZO, or ITO.

The first semiconductor layer T1 may be formed using an oblique angle deposition (OAD) method. Oblique angle deposition (OAD) may refer to a method of performing deposition by tilting a deposition direction at a certain angle other than a vertical angle when the deposition is performed on an upper surface of the first metal material layer ML1. According to the oblique angle deposition method, a deposition material may be obliquely incident on the upper surface of the metal material layer ML1 so that masking occurs in some areas. That is, a first non-deposition area SA1 where the deposition is not performed may be formed. A width of a non-deposition area may vary according to a thickness of the photosensitive pattern and/or an angle of the deposition of the oblique angle deposition method.

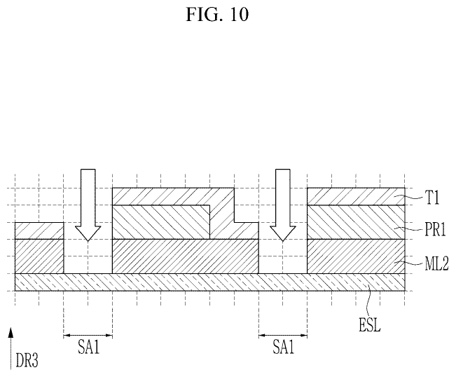

Then, as shown in FIG. 10, an etching process may be performed using the first semiconductor layer T1 as a mask. For example, the etching process may be a dry etching process. In the etching process, the first metal material layer ML1 disposed in the non-deposition area SA1 may be removed to form a second metal material layer ML2. Damage to layers disposed below the etching prevention material layer ESL may be prevented by the etching prevention material layer ESL.

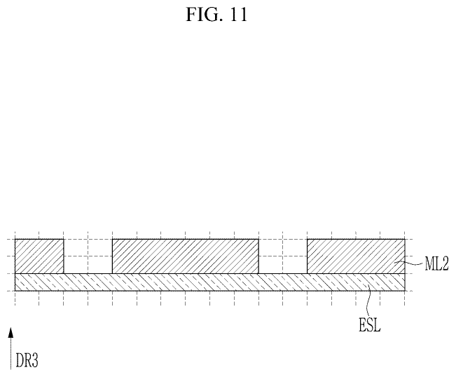

Thereafter, as shown in FIG. 11, the first photosensitive pattern PR1 and the first semiconductor layer T1 may be removed to provide the second metal material layer ML2.

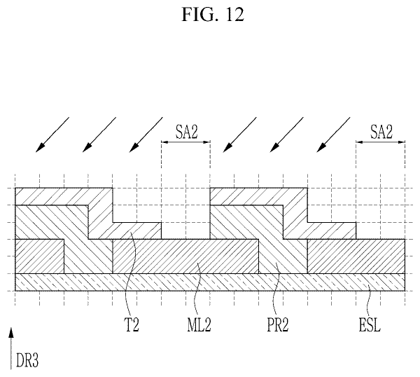

Next, as shown in FIG. 12, a second photosensitive pattern PR2 may be formed on the second metal material layer ML2 and the etching prevention material layer ESL using the exposure machine. A portion of the second photosensitive pattern PR2 may be disposed on the second metal material layer ML2. Another portion of the second photosensitive pattern PR2 may be disposed on the etching prevention material layer ESL. The second photosensitive pattern PR2 may have a step difference.

Then, a second semiconductor layer T2 may be formed on the second photosensitive pattern PR2 and the second metal material layer ML2 using the oblique angle deposition (OAD) method. If the oblique angle deposition (OAD) method is used, a second non-deposition area SA2 where an oxide semiconductor is not deposited may be formed.

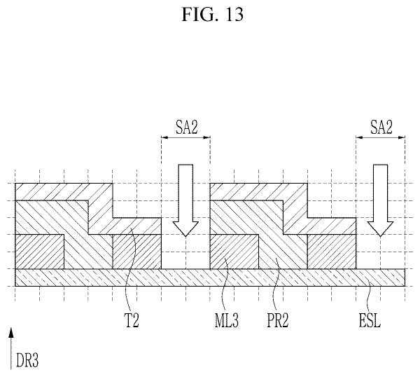

Then, as shown in FIG. 13, an etching process may be performed using the second semiconductor layer T2 as a mask. The second metal material layer ML2 that is disposed in the second non-deposition area SA2 may be removed, and a third metal material layer ML3 may be formed.

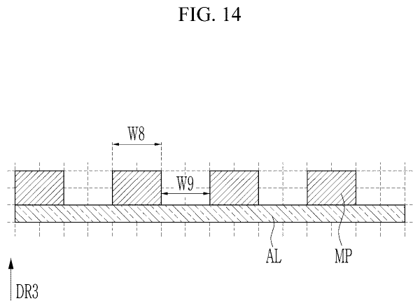

Thereafter, as shown in FIG. 14, the second semiconductor layer T2 and the second photosensitive pattern PR2 may be removed to form the plurality of metal patterns MP.

According to the manufacturing process described above, the width W6 of the photosensitive pattern PR1 of FIG. 8 may be larger than a width W8 of the metal pattern MP of FIG. 14. Additionally, the interval W7 between the adjacent photosensitive patterns PR1 of FIG. 8 may be larger than an interval W9 between adjacent metal patterns MP of FIG. 14. For example, if the etching process is repeatedly performed twice, the width W8 of the metal pattern MP or the interval W9 between the adjacent metal patterns MP may be half the width W6 of the photosensitive pattern PR1.

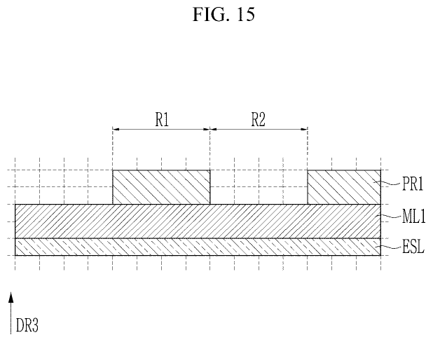

Hereinafter, an embodiment in which the above-described manufacturing process is additionally repeated with reference to FIGS. 15 to 26 will be described. A description of the same components as those described above will be omitted.

Referring to FIG. 15, an etching prevention material layer ESL may be formed. The etching prevention material layer ESL may include transparent conductive oxide (TCO).

The first metal material layer ML1 may be formed on the etching prevention material layer ESL. The first metal material layer ML1 may have a generally flat thickness.

The first photosensitive pattern PR1 may be disposed on the first metal material layer ML1. A plurality of first photosensitive patterns PR1 may be disposed on the first metal material layer ML1. The plurality of first photosensitive patterns PR1 may be repeatedly disposed. The plurality of first photosensitive patterns PR1 may be disposed at regular intervals from each other. A width R1 of the first photosensitive pattern PR1 and an interval R2 between adjacent first photosensitive patterns PR1 may be the same. For example, the width R1 of the first photosensitive pattern PR1 may be about 1 micrometer and the interval R2 between the adjacent first photosensitive patterns PR1 may be about 1 micrometer.

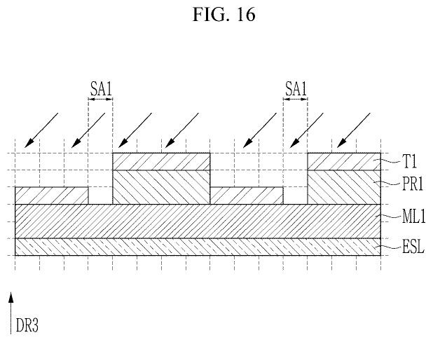

Next, referring to FIG. 16, the first semiconductor layer T1 may be deposited on the first photosensitive pattern PR1. The first semiconductor layer T1 may be deposited using an oblique angle deposition (OAD) method. If the oblique angle deposition (OAD) method is used, a first non-deposition area SA1 where a semiconductor material is not deposited may be formed according to a height of the first photosensitive pattern PR1 and/or an angle of the oblique angle deposition (OAD).

Then, an etching process may be performed using the first semiconductor layer T1 as a mask. For example, the etching process may be a dry etching process. In the etching process, the first metal material layer ML1 disposed in the first non-deposition area SA1 may be removed. Damage to a lower layer disposed below the etching prevention material layer ESL may be prevented by the etching prevention material layer ESL.

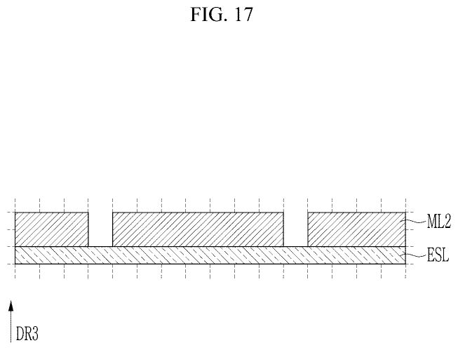

Thereafter, as shown in FIG. 17, the first photosensitive pattern PR1 and the first semiconductor layer T1 may be removed to form the second metal material layer ML2.

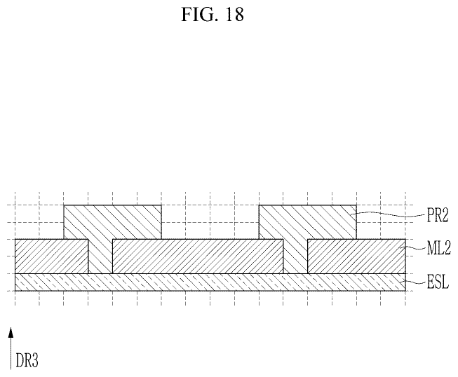

Next, as shown in FIG. 18, a second photosensitive pattern PR2 may be formed on the second metal material layer ML2 and the etching prevention material layer ESL using the same exposure machine. A portion of the second photosensitive pattern PR2 may be disposed on the second metal material layer ML2. Another portion of the second photosensitive pattern PR2 may be disposed on the etching prevention material layer ESL.

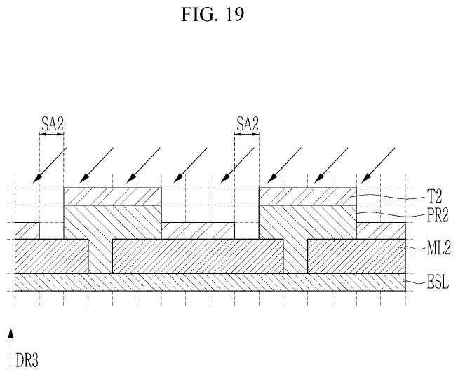

Then, as shown in FIG. 19, a second semiconductor layer T2 may be formed on the second photosensitive pattern PR2 and the second metal material layer ML2 using the oblique angle deposition (OAD) method. If the oblique angle deposition (OAD) method is used, a second non-deposition area SA2 where an oxide semiconductor is not deposited may be formed. The second non-deposition area SA2 may be disposed on the second metal material layer ML2.

Then, an etching process may be performed using the second semiconductor layer T2 as a mask. The second metal material layer ML2 that is disposed in the second non-deposition area SA2 may be removed.

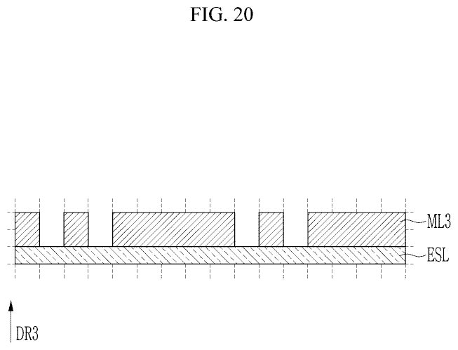

Thereafter, as shown in FIG. 20, the second semiconductor layer T2 and the second photosensitive pattern PR2 may be removed to form a third metal material layer ML3.

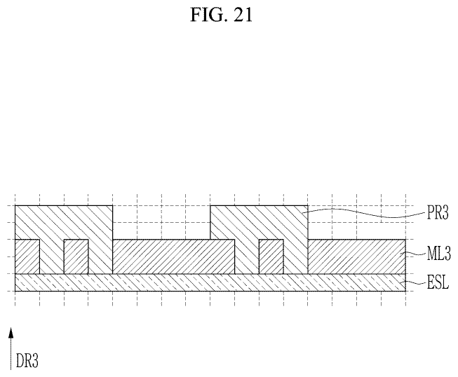

Next, as shown in FIG. 21, a third photosensitive pattern PR3 may be formed on the third metal material layer ML3 and the etching prevention material layer ESL using the same exposure machine. A portion of the third photosensitive pattern PR3 may be disposed on the third metal material layer ML3. A portion of the third photosensitive pattern PR3 may be disposed on the etching prevention material layer ESL. A portion of the third photosensitive pattern PR3 may be disposed between adjacent third metal material layers ML3.

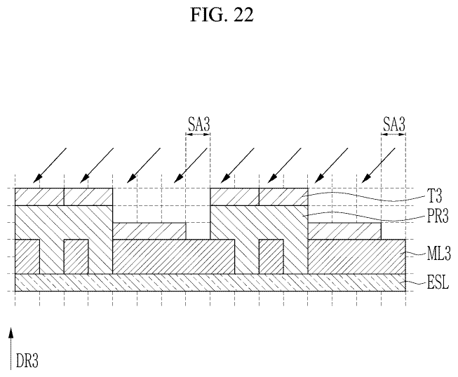

Then, as shown in FIG. 22, a third semiconductor layer T3 may be formed on the third photosensitive pattern PR3 and the third metal material layer ML3 using the oblique angle deposition (OAD) method. If the oblique angle deposition (OAD) method is used, a third non-deposition area SA3 where an oxide semiconductor is not deposited may be formed. The third non-deposition area SA3 may be an area where the third metal material layer ML3 is disposed.

Then, an etching process may be performed using the third semiconductor layer T3 as a mask. The third metal material layer ML3 that is disposed in the third non-deposition area SA3 may be removed.

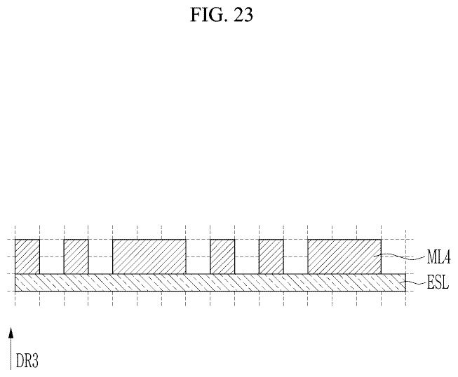

Thereafter, as shown in FIG. 23, the third semiconductor layer T3 and the third photosensitive pattern PR3 may be removed to form a fourth metal material layer ML4.

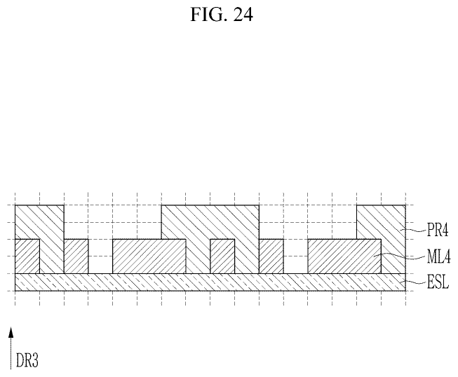

Next, as shown in FIG. 24, a fourth photosensitive pattern PR4 may be formed on the fourth metal material layer ML4 and the etching prevention material layer ESL using the same exposure machine. A portion of the fourth photosensitive pattern PR4 may be disposed on the fourth metal material layer ML4. Another portion of the fourth photosensitive pattern PR4 may be disposed on the etching prevention material layer ESL.

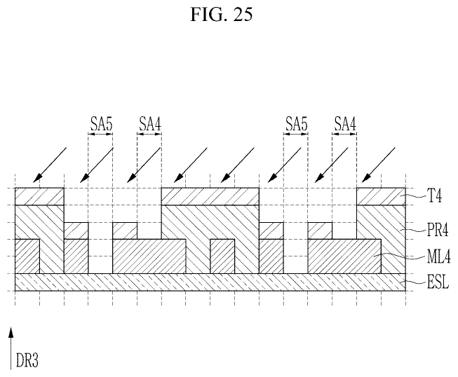

Then, as shown in FIG. 25, a fourth semiconductor layer T4 may be formed on the fourth photosensitive pattern PR4 and the fourth metal material layer ML4 using an oblique angle deposition (OAD) method. If the oblique angle deposition (OAD) method is used, a fourth non-deposition area SA4 where a semiconductor material is not deposited may be formed. The fourth non-deposition area SA4 may be disposed on the fourth metal material layer ML4.

Then, an etching process may be performed using the fourth semiconductor layer T4 as a mask. The fourth metal material layer ML4 that is disposed in the fourth non-deposition area SA4 may be removed.

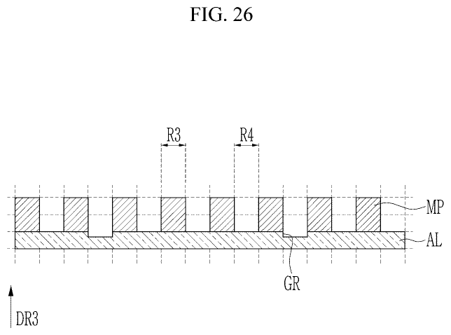

Thereafter, as shown in FIG. 26, the fourth semiconductor layer T4 and the fourth photosensitive pattern PR4 may be removed to form the plurality of metal patterns MP.

Referring to FIG. 26, according to an embodiment, the first layer AL (ESL) may include the groove GR. Referring to a manufacturing process, the groove GR of the first layer AL of FIG. 25 may be an area exposed twice in the etching process of FIG. 24 and the etching process of FIG. 16. In FIG. 25, a fifth non-deposition area SA5 may be an area that is relatively more exposed to the etching process than other areas.

According to the manufacturing process of FIGS. 15 to 26, the width of the photosensitive pattern PR1 (R1 of FIG. 15) may be larger than the width of the metal pattern MP (R3 of FIG. 26). The interval R2 between adjacent photosensitive patterns PR1 of FIG. 15 may be larger than an interval R4 between adjacent metal patterns MP of FIG. 26. For example, if the etching process is performed four times, the width R3 of the metal pattern MP may be a quarter of the width R1 of the photosensitive pattern PR1. According to an embodiment, the metal patterns may be formed at small intervals compared with an exposure capability of the exposure machine. Because the above-described manufacturing process is repeated N times, a metal pattern having a width of 1/N of the exposure capability of the exposure machine may be provided. That is, it may be possible to provide the wire grid polarizer having a fine pattern regardless of the exposure capability of the exposure machine.

While this disclosure has been described in connection with what is presently considered to be practical embodiments, it should be understood that the disclosure is not limited to the disclosed embodiments, but, on the contrary, is intended to cover various modifications and equivalent arrangements included within the spirit and scope of the appended claims.

What is claimed is:

1. A wire grid polarizer, comprising:
a first layer; and
a plurality of metal patterns that are disposed on the first layer and have good etching selectivity to the first layer,
wherein the first layer includes at least one groove.

2. The wire grid polarizer of claim 1, wherein the at least one groove is disposed between metal patterns adjacent to each other.

3. The wire grid polarizer of claim 1, wherein the first layer includes a transparent conductive oxide.

4. The wire grid polarizer of claim 3, wherein the first layer includes a plurality of grooves and the plurality of grooves are repeatedly disposed.

5. The wire grid polarizer of claim 3, wherein the first layer includes a plurality of grooves, the plurality of grooves includes a first groove and a second groove, and the first groove and the second groove have different depths.

6. An electronic device comprising a display device,
wherein the display device includes a display layer including a light emitting device and a wire grid polarizer disposed on the display layer, the wire grid polarizer includes a first layer including a transparent conductive oxide and a plurality of metal patterns disposed on the first layer and having good etching selectivity to the first layer, and
wherein the first layer includes at least one groove.

7. The electronic device of claim 6, wherein the first layer includes a plurality of grooves and the plurality of grooves are repeatedly disposed.

8. The electronic device of claim 7, wherein the plurality of grooves includes a first groove and a second groove, and the first groove and the second groove have different depths.

9. A manufacturing method of a wire grid polarizer, comprising:
forming a first metal material layer on an etching prevention material layer;
forming a first photosensitive pattern on the first metal material layer;
forming a first semiconductor layer on the first photosensitive pattern by an oblique angle deposition method; and
etching the first metal material layer using the first semiconductor layer as a mask to form a second metal material layer.

10. The manufacturing method of claim 9, further comprising removing the first photosensitive pattern and the first semiconductive layer after etching the first metal material layer.

11. The manufacturing method of claim 10, further comprising:
forming a second photosensitive pattern on the second metal material layer and the etching prevention material layer;
forming a second semiconductor layer on the second photosensitive pattern by an oblique angle deposition method; and
etching the second metal material layer using the second semiconductor layer as a mask.

12. The manufacturing method of claim 11, further comprising removing the second photosensitive pattern and the second semiconductor layer.

13. The manufacturing method of claim 12, wherein the first layer includes at least one groove.

14. The manufacturing method of claim 12, wherein the first layer includes a plurality of grooves, and the plurality of grooves are repeatedly disposed.

15. The manufacturing method of claim 14, wherein the plurality of grooves includes a first groove and a second groove, and the first groove and the second groove have different depths.

16. The manufacturing method of claim 12, wherein an interval between the metal patterns adjacent to each other is less than a width of the first photosensitive pattern.

17. The manufacturing method of claim 9, wherein the first semiconductor layer is deposited on the first metal material layer in an oblique deposition direction through the oblique angle deposition method.

18. The manufacturing method of claim 17, wherein a non-deposition area where the first semiconductor layer is not disposed is formed through the oblique angle deposition method.

19. The manufacturing method of claim 18, wherein the first metal material layer overlapping the non-deposition area is removed.
